(19) United States
(12) Patent Application Publication
(10) Pub. No.: US 2024/0240870 A1
(43) Pub. Date: Jul. 18, 2024

(54) HEAT EXCHANGER MOUNTING DEVICE

(71) Applicant: PURPLE CLOUD DEVELOPMENT PTE. LTD., Singapore (SG)

(72) Inventors: Hsiang-Chieh TSENG, Singapore (SG); Wei-Pin LIN, Singapore (SG)

(73) Assignee: PURPLE CLOUD DEVELOPMENT PTE. LTD., Singapore (SG)

(21) Appl. No.: 18/414,559

(22) Filed: Jan. 17, 2024

(30) Foreign Application Priority Data
Jan. 17, 2023 (TW) 112101992

(51) Int. Cl. F28D 9/00; F28F 1/40; F28F 3/02

(52) U.S. Cl. CPC F28D 9/0043; F28F 1/40; F28F 3/025

(57) ABSTRACT

A heat exchanger mounting device including a device plate, at least one securing device, and at least one cage is provided. The at least one securing device includes a barrel and pin. A first barrel end of the barrel is incorporated in at least one opening of the device plate. An augmented head of the pin extends at least partially through and rotatable in the barrel. The at least one cage is mounted on a heat exchanger. The augmented head extends through a cage opening of the at least one cage in a first direction. The augmented head rotates within the at least one cage in a second direction to secure the at least one securing device to the heat exchanger. The weight of the heat exchanger is substantially supported by the at least one securing device by way of the at least one cage and augmented head.

### RELATED APPLICATIONS

This US application claims the benefit of priority to Taiwan application No. 112101992, filed on Jan. 17, 2023, of which is incorporated herein by reference in its entirety.

### TECHNICAL FIELD

The present disclosure is related to the field of heat transfer in general and more particularly but not limited to mounting of multiple heat exchangers in electronic systems.

### BACKGROUND

With the increase of the processing speed and performance of electronic components, such as application-specific integrated circuits (ASICs) and central processing units (CPU), the amount of heat generated during the operation of the electronic component increases. The heat generation increases the temperature of the electronic component and, if the heat cannot be dissipated effectively, the reliability and performance of the electronic component are reduced.

To prevent overheating of electronic components, heat exchangers may be used. A heat exchanger may be mounted to a circuit board, before being loaded in an electronic system. A heat exchanger mounting device may be used to load the heat exchanger in the electronic system. Multiple fasteners may be used to secure the heat exchanger mounting device to the heat exchanger. Often, the multiple fasteners are secured by screwing via a screwdriver, whereby the fasteners may wear in such a way that debris is created from multiple torque cycles. The debris may cause the electronic components to fail. The heat exchanger mounting device is screwed to the heat exchanger to load the heat exchanger in the electronics system, and unscrewed from the heat exchanger to remove the heat exchanger mounting device from the heat exchanger after being loaded. Screwing of the multiple fasteners is time consuming. The debris and screwing are exasperated when multiple heat exchangers mounted to a circuit board are loaded in the electronics system.

### SUMMARY

Aspects of the present disclosure provide a heat exchanger mounting device including a device plate, at least one securing device, and at least one cage. The device plate can include at least one opening. The at least one securing device can include a barrel and a pin, the barrel can include a first barrel end and a second barrel end opposite the first barrel end, the first barrel end incorporated in the at least one opening, the pin can include a first end and a second end opposite the first end, the second end can include an augmented head, the augmented head extending at least partially through the barrel and rotatable in the barrel. The at least one cage can include a cage body, the cage body can include a cage opening receiving the augmented head, wherein the at least one cage is mounted on a heat exchanger, wherein the augmented head extends through the cage opening in a first direction, and wherein the augmented head rotates within the at least one cage in a second direction different from the first direction to secure the at least one securing device to the heat exchanger, whereby a weight of the heat exchanger thereby is substantially supported by the at least one securing device by way of the at least one cage and augmented head.

In at least one embodiment, an angle of rotation of the second direction from the first direction is between 0 degrees to 180 degrees and between 0 degrees to −180 degrees, respectively.

In at least one embodiment, the cage body can further include a pair of inward-facing overhangs. Each pair of inward-facing overhangs is disposed on opposing sides of the cage opening and at least partially defines a receiving cavity, whereby the augmented head is rotatable in the receiving cavity. In at least one embodiment, the augmented head can include a pair of side flat cut outs and a pair of ledges. Each pair of side flat cut outs is disposed on opposing sides of the augmented head and each pair of ledges is disposed on opposing sides of the augmented head different from each pair of side flat cut outs. The augmented head extends through the cage opening in the first direction by way of each pair of side flat cut outs corresponding to each pair of inward-facing overhangs. The weight of the heat exchanger is substantially supported by the at least one securing device by way of the augmented head in the second direction and at least a part of a top surface of each pair of ledges at least partially being flush against at least a part of a bottom surface of each pair of inward-facing overhangs in the receiving cavity, respectively.

In at least one embodiment, the barrel can further include a bore and an internal shoulder. The bore disposed through the barrel from the first barrel end to the second barrel end. The internal shoulder is disposed in the bore between the first barrel end and the second barrel end. The at least one securing device can further include an internal retaining ring, a thrust device, and a spring. The internal retaining ring is incorporated in the bore at the first barrel end. The thrust device is incorporated surrounding the pin and between the internal retaining ring and the internal shoulder. The spring includes a spring first end and a spring second end. The spring is disposed surrounding the pin and between the thrust device and the internal shoulder. The spring first end is disposed flush with a bottom thrust surface of the thrust device by way of an upward force and the spring second end is disposed flush with a top shoulder surface of the internal shoulder by way of a downward force. The pin is pushed in a downward direction to extend the augmented head through the cage opening, and the pin is rotated to the second direction to substantially support the weight of the heat exchanger by the at least one securing device.

In at least one embodiment, the first end can include a knob, whereby the knob is rotated to the second direction and is visually identifiable in the second direction and the knob is rotated to the first direction and is visually identifiable in the first direction. In at least one embodiment, the heat exchanger mounting device can further include at least one handle. The at least one handle is incorporated on the device plate. In at least one embodiment, the at least one handle can include two handles. In at least one embodiment, the heat exchanger is mounted on a circuit board.

In at least one embodiment, the at least one opening can include two at least one opening, the at least one securing device includes two at least one securing device, and the at least one cage includes two at least one cage. Each of the at least one securing device correspond to each of the at least one opening and each of the at least one cage, respectively. In at least one embodiment, the heat exchanger mounting device can further include a total of eight heat exchangers, a total of sixteen openings, a total of sixteen securing devices, and a total of sixteen cages, each of the securing device correspond to one opening and one cage, respectively.

Aspects of the present disclosure provide a heat exchanger mounting device system. The heat exchanger mounting device system can include a device plate, at least one securing device, at least one cage, and at least one heat exchanger. The device plate can include at least one opening. The at least one securing device can include a barrel and a pin. The barrel can include a first barrel end and a second barrel end opposite the first barrel end. The first barrel end is incorporated in the at least one opening. The pin can include a first end and a second end opposite the first end. The second end can include an augmented head extending at least partially through the barrel and rotatable in the barrel. The at least one cage can include a cage body having a cage opening receiving the augmented head. The at least one heat exchanger can include an inlet port and an outlet port. The inlet port and the outlet port are incorporated on the at least one heat exchanger, respectively. The at least one cage is mounted on the at least one heat exchanger. The augmented head extends through the cage opening in a first direction and rotates within the at least one cage in a second direction different from the first direction. In the second direction, the at least one securing device is secured to the at least one heat exchanger, whereby the weight of the at least one heat exchanger thereby is substantially supported by the at least one securing device by way of the at least one cage and augmented head.

In at least one embodiment, an angle of rotation of the second direction from the first direction is between 0 degrees to 180 degrees and between 0 degrees to −180 degrees, respectively.

In at least one embodiment, the at least one heat exchanger can further include two at least one heat exchanger, and the heat exchanger mounting device system can further include an inlet manifold, an outlet manifold, an inlet conduit, an outlet conduit, a plurality of heat exchanger inlet conduits, a plurality of heat exchanger outlet conduits, and a circuit board. An inlet manifold end of the inlet conduit is mounted to a manifold inlet of the inlet manifold and an outlet manifold end of the outlet conduit is mounted to a manifold outlet of the outlet manifold. A heat exchanger inlet conduit end of each plurality of heat exchanger inlet conduits is mounted to each of a plurality of heat exchanger outlets of the inlet manifold and a heat exchanger outlet conduit end of each plurality of heat exchanger outlet conduits is mounted to each of a plurality of heat exchanger inlets of the outlet manifold. A heat exchanger outlet conduit end of each plurality of heat exchanger inlet conduits is mounted to the inlet port and a heat exchanger inlet conduit end of each plurality of heat exchanger outlet conduits is mounted to the outlet port. Each of the at least one heat exchangers is mounted on the circuit board.

In at least one embodiment, the heat exchanger mounting device system can further include a total of eight heat exchangers, a total of sixteen openings, a total of sixteen securing devices, and a total of sixteen cages, wherein each of the securing device correspond to one opening and one cage, respectively. In at least one embodiment, the at least one heat exchanger can further include an assembly plate, a water block cover, a water block body, and a water block base. The water block body can include a base cavity opening. The water block base can include a plurality of heat transfer surface features incorporated on the water block base. The plurality of heat transfer surface features correspond to the base cavity opening. The water block body is mounted on the water block base. The assembly plate can include a pair of port openings and a pair of cage openings. The inlet port and the outlet port are mounted on the water block cover, respectively. The inlet port and the outlet port correspond to the pair of port openings, respectively. The cage body of each at least one cage correspond to the pair of cage openings, respectively. Each at least one cage is mounted to the at least one heat exchanger by way of the pair of cage openings, respectively. The assembly plate is mounted on the water block body and the water block cover mounted between the assembly plate and the water block body.

In at least one embodiment, the cage body can further include a pair of inward-facing overhangs. Each pair of inward-facing overhangs is disposed on opposing sides of the cage opening and each pair of inward-facing overhangs at least partially defines a receiving cavity. The augmented head is rotatable in the receiving cavity. In at least one embodiment, the augmented head can include a pair of side flat cut outs and a pair of ledges. Each pair of side flat cut outs is disposed on opposing sides of the augmented head and each pair of ledges is disposed on opposing sides of the augmented head different from each pair of side flat cut outs. The augmented head extends through the cage opening in the first direction by way of each pair of side flat cut outs corresponding to each pair of inward-facing overhangs. The weight of the at least one heat exchanger is substantially supported by the at least one securing device by way of the augmented head in the second direction and at least a part of a top surface of each pair of ledges at least partially being flush against at least a part of a bottom surface of each pair of inward-facing overhangs in the receiving cavity, respectively.

In at least one embodiment, the barrel can further include a bore and an internal shoulder. The bore is disposed through the barrel from the first barrel end to the second barrel end. The internal shoulder is disposed in the bore between the first barrel end and the second barrel end. The at least one securing device can further include an internal retaining ring, a thrust device, and a spring. The internal retaining ring is incorporated in the bore at the first barrel end and the thrust device is incorporated surrounding the pin and between the internal retaining ring and the internal shoulder. The spring can include a spring first end and a spring second end and is disposed surrounding the pin and between the thrust device and the internal shoulder. The spring first end is disposed flush with a bottom thrust surface of the thrust device by way of an upward force and the spring second end disposed flush with a top shoulder surface of the internal shoulder by way of a downward force. The pin is pushed in a downward direction to extend the augmented head through the cage opening and the pin is rotated to the second direction to substantially support the weight of the at least one heat exchanger by the at least one securing device.

In at least one embodiment, the heat exchanger mounting device system can further include at least one handle, and the first end can include a knob. The at least one handle is incorporated on the device plate. The knob is rotated to the second direction and is visually identifiable in the second direction and the knob is rotated to the first direction and is visually identifiable in the first direction.

### BRIEF DESCRIPTION OF DRAWINGS

Unless specified otherwise, the accompanying drawings illustrate aspects of the innovative subject matter described herein. Referring to the drawings, wherein like reference numerals indicate similar parts throughout the several views, several examples of vapor chambers incorporating aspects of the presently disclosed principles are illustrated by way of example, and not by way of limitation.

FIG. 1A shows a perspective view of a heat exchanger mounting device system according to one embodiment of the present disclosure.

FIG. 1B shows an exploded view of the heat exchanger mounting device system of FIG. 1 according to one embodiment of the present disclosure.

FIG. 2 shows a cross-sectional view of a securing device and a cage of the heat exchanger mounting device of FIG. 1 according to one embodiment of the present disclosure.

FIG. 3 shows an exploded view of a heat exchanger and a cage of the heat exchanger mounting device system of FIG. 1 according to one embodiment of the present disclosure.

FIG. 4 shows a top partially internal view of a heat exchanger and a cage of the heat exchanger mounting device system of FIG. 1 according to one embodiment of the present disclosure.

FIGS. 5A to 5C show a process of securing a heat exchanger mounting device to a heat exchanger according to the present disclosure.

### DETAILED DESCRIPTION

The following describes various principles related to mounting of heat exchangers in electronic systems by way of reference to specific examples of heat exchangers and heat exchanger mounting devices, including specific arrangements and examples of securing devices and cages embodying innovative concepts. More particularly, but not exclusively, such innovative principles are described in relation to selected examples of augmented heads and cages, whereby a weight of the heat exchangers is substantially supported by the securing device by way of the cage and augmented head, and well-known functions or constructions are not described in detail for purposes of succinctness and clarity. Nonetheless, one or more of the disclosed principles can be incorporated in various other embodiments of augmented heads and cages to achieve any of a variety of desired outcomes, characteristics, and/or performance criteria.

Thus, heat exchanger mounting devices having attributes that are different from those specific examples discussed herein can embody one or more of the innovative principles, and can be used in applications not described herein in detail. Accordingly, embodiments of heat exchanger mounting devices not described herein in detail also fall within the scope of this disclosure, as will be appreciated by those of ordinary skill in the relevant art following a review of this disclosure.

Example embodiments as disclosed herein are directed to heat exchanger mounting devices including at least one securing device and at least one cage. The at least one securing device can include a barrel and a pin, wherein an augmented head of the pin extends at least partially through and rotatable in the barrel. The at least one cage is mounted on a heat exchanger. The pin is pushed in a downward direction to extend the augmented head through a cage opening of the at least one cage in a first direction. The pin is rotated to a second direction, which in turn rotates the augmented head, to secure the at least one securing device to the heat exchanger. The weight of the heat exchanger is substantially supported by the at least one securing device by way of the at least one cage and augmented head, without screwing.

The heat exchanger mounting devices may be configured within an electric or electronics system that includes heat producing electronic components to be cooled.

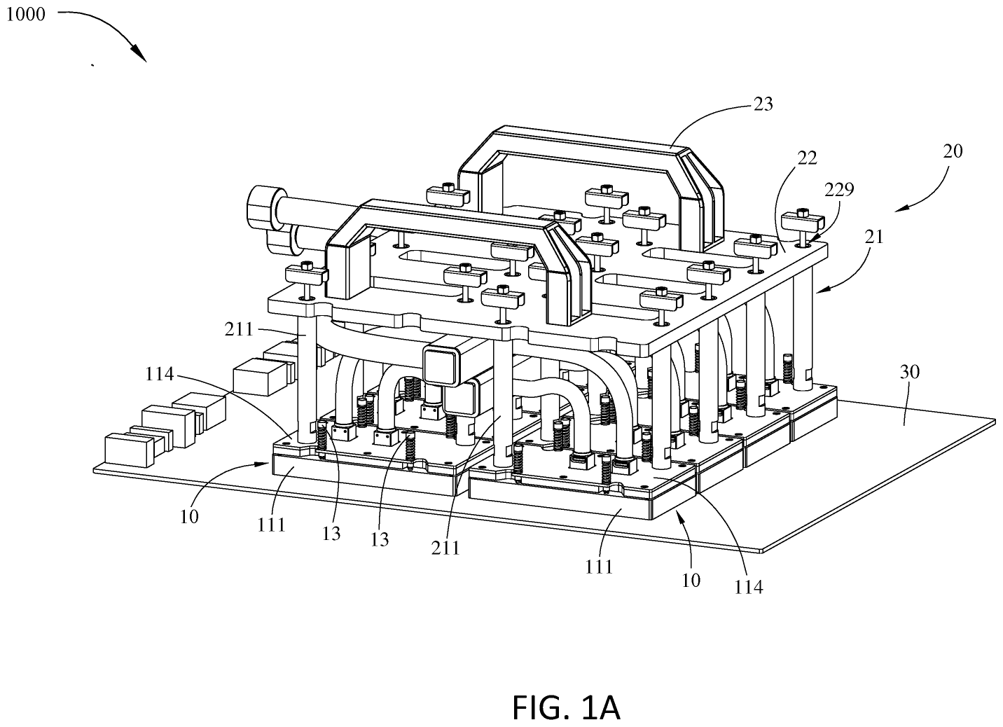

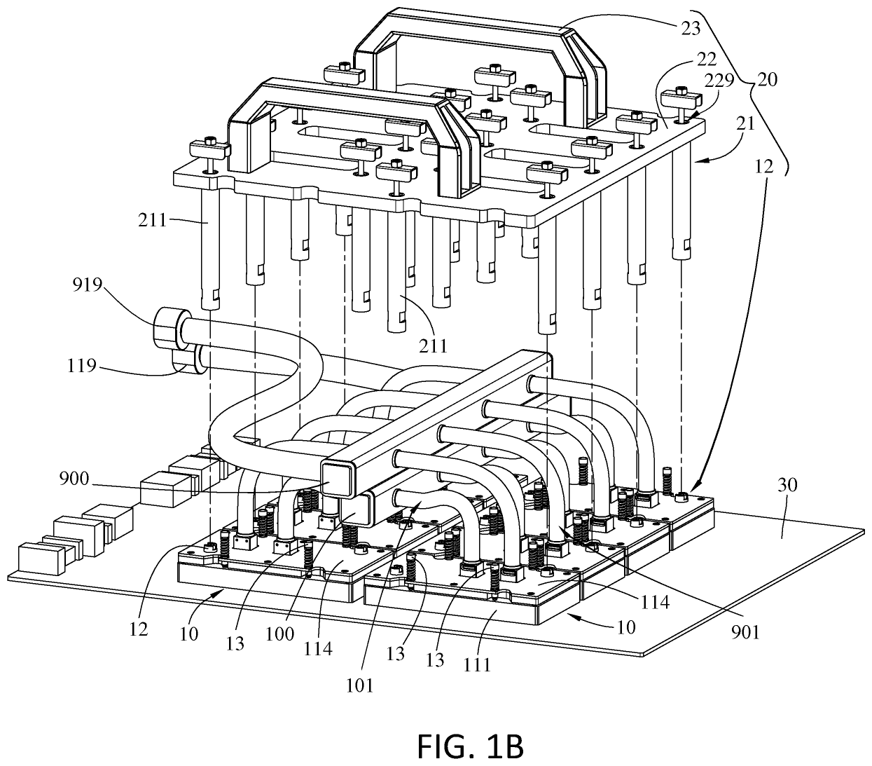

FIG. 1A shows a perspective view of a heat exchanger mounting device system 1000 according to the embodiments of the present disclosure. The heat exchanger mounting device system 1000 can include a heat exchanger 10, a heat exchanger mounting device 20, and a circuit board 30. FIG. 1B shows a exploded view of the heat exchanger mounting device system 1000 of FIG. 1A. The heat exchanger mounting device 20 includes a device plate 22, at least one securing device 21, and at least one cage 12. The device plate 22 includes at least one opening 229 and may be quadrilateral shaped.

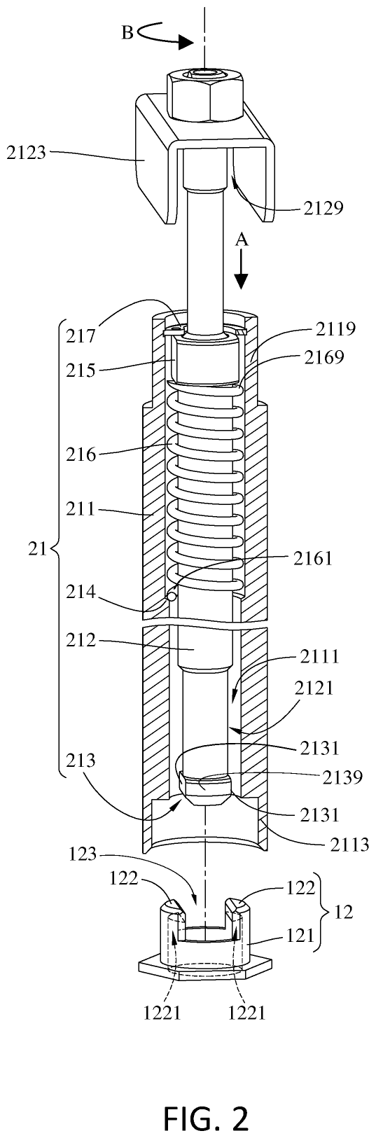

FIG. 2 shows a cross-sectional view of the securing device 21 and the cage 12 of the heat exchanger mounting device 20. The at least one securing device 21 includes a barrel 211 and a pin 212. The barrel 211 includes a first barrel end 2119 and a second barrel end 2113 opposite the first barrel end 2119. The first barrel end 2119 is incorporated in the at least one opening 229. The barrel 211 may be cylindrical shaped. The pin 212 includes a first end 2129 and a second end 2121 opposite the first end 2129. The second end 2121 includes an augmented head 213 extending at least partially through the barrel 211 and rotatable in the barrel 211. A diameter of the augmented head 213 is greater than a diameter of the second end 2121. The at least one cage 12 includes a cage body 121 having a cage opening 123 receiving the augmented head 213. The at least one cage 12 is mounted on the heat exchanger 10 and extends perpendicularly from the heat exchanger 10. The at least one cage 12 may be mounted on the heat exchanger 10 by way of riveting. The augmented head 213 extends through the cage opening 123 in a first direction (e.g., downward direction A) and rotates within the at least one cage 12 in a second direction (e.g., direction B) different from the first direction. The augmented head 213 may rotate in a vertical axis. In the second direction, the at least one securing device 21 is secured to the heat exchanger 10, whereby a weight of the heat exchanger 10 thereby is substantially supported by the at least one securing device 21 by way of the at least one cage 12 and augmented head 213. In at least one embodiment, an angle of rotation of the second direction from the first direction is between 0 degrees to 180 degrees and between 0 degrees to −180 degrees, respectively.

In at least one embodiment, the cage body 121 further includes a pair of inward-facing overhangs 122. Each pair of inward-facing overhangs 122 is disposed on opposing sides of the cage opening 123 and at least partially defines a receiving cavity 1221, whereby the augmented head 213 is rotatable in the receiving cavity 1221. In at least one embodiment, the augmented head 213 includes a pair of side flat cut outs 2131 and a pair of ledges 2139. The augmented head 213 may be a nut-like shape. Each pair of side flat cut outs 2131 is disposed on opposing sides of the augmented head 213 and each pair of ledges 2139 is disposed on opposing sides of the augmented head 213 different from each pair of side flat cut outs 2131. The augmented head 213 extends through the cage opening 123 in the first direction by way of each pair of side flat cut outs 2131 corresponding to each pair of inward-facing overhangs 122. The weight of the heat exchanger 10 is substantially supported by the at least one securing device 21 by way of the augmented head 213 in the second direction and at least a part of a top surface of each pair of ledges 2139 at least partially being flush against at least a part of a bottom surface of each pair of inward-facing overhangs 122 in the receiving cavity 1221, respectively.

In at least one embodiment, the barrel 211 further includes a bore 2111 and an internal shoulder 214. The bore 2111 is disposed through the barrel 211 from the first barrel end 2119 to the second barrel end 2113. The internal shoulder 214 is disposed in the bore 2111 between the first barrel end 2119 and the second barrel end 2113. The at least one securing device 21 further includes an internal retaining ring 217, a thrust device 215, and a spring 216. The internal retaining ring 217 is incorporated in the bore 2111 at the first barrel end 2119. The thrust device 215 is incorporated surrounding the pin 212 and between the internal retaining ring 217 and the internal shoulder 214. A diameter of the pin 212 surrounded by the thrust device 215 is greater than a diameter of the pin 212 surrounded by the internal retaining ring 217. The spring 216 includes a spring first end 2169 and a spring second end 2161. The spring 216 is disposed surrounding the pin 212 and between the thrust device 215 and the internal shoulder 214. The spring first end 2169 is disposed flush with a bottom thrust surface of the thrust device 215 by way of an upward force and the spring second end 2161 is disposed flush with a top shoulder surface of the internal shoulder 214 by way of a downward force. The thrust device 215 is flush with a ring bottom of the internal retaining ring 217, before the pin 212 is pushed in the downward direction A to extend the augmented head 213 through the cage opening 123, and the pin 212 is rotated along the direction B to the second direction to substantially support the weight of the heat exchanger 10 by the at least one securing device 21. In at least one embodiment, the first end 2129 includes a knob 2123, whereby the knob 2123 is rotated along the direction B to the second direction and is visually identifiable in the second direction and the knob 2123 is rotated to the first direction and is visually identifiable in the first direction.

Refer back to FIG. 1B, each of the at least one securing device 21 corresponds to at least one opening 229 and at least one cage 12. In at least one embodiment, the heat exchanger mounting device 20 can further include at least one handle 23 as shown in FIG. 1B. The at least one handle 23 is incorporated on the device plate 22. In at least one embodiment, the heat exchanger mounting device 20 can include two handles 23 as shown in FIG. 1B. In at least one embodiment, the heat exchanger mounting device system 1000 can include eight heat exchangers 10, sixteen openings 229, sixteen securing devices 21, and sixteen cages 12. The heat exchanger mounting device system 1000 can further include an inlet manifold 100, an outlet manifold 900, an inlet conduit 119, an outlet conduit 919, a plurality of heat exchanger inlet conduits 101, and a plurality of heat exchanger outlet conduits 901. An inlet manifold end of the inlet conduit 119 is mounted to a manifold inlet of the inlet manifold 100 and an outlet manifold end of the outlet conduit 919 is mounted to a manifold outlet of the outlet manifold 900. A heat exchanger inlet conduit end of each plurality of heat exchanger inlet conduits 101 is mounted to each of a plurality of heat exchanger outlets of the inlet manifold 100 and a heat exchanger outlet conduit end of each plurality of heat exchanger outlet conduits 901 is mounted to each of a plurality of heat exchanger inlets of the outlet manifold 900. A heat exchanger outlet conduit end of each plurality of heat exchanger inlet conduits 101 is mounted to the inlet port 115 and a heat exchanger inlet conduit end of each plurality of heat exchanger outlet conduits 901 is mounted to the outlet port 116.

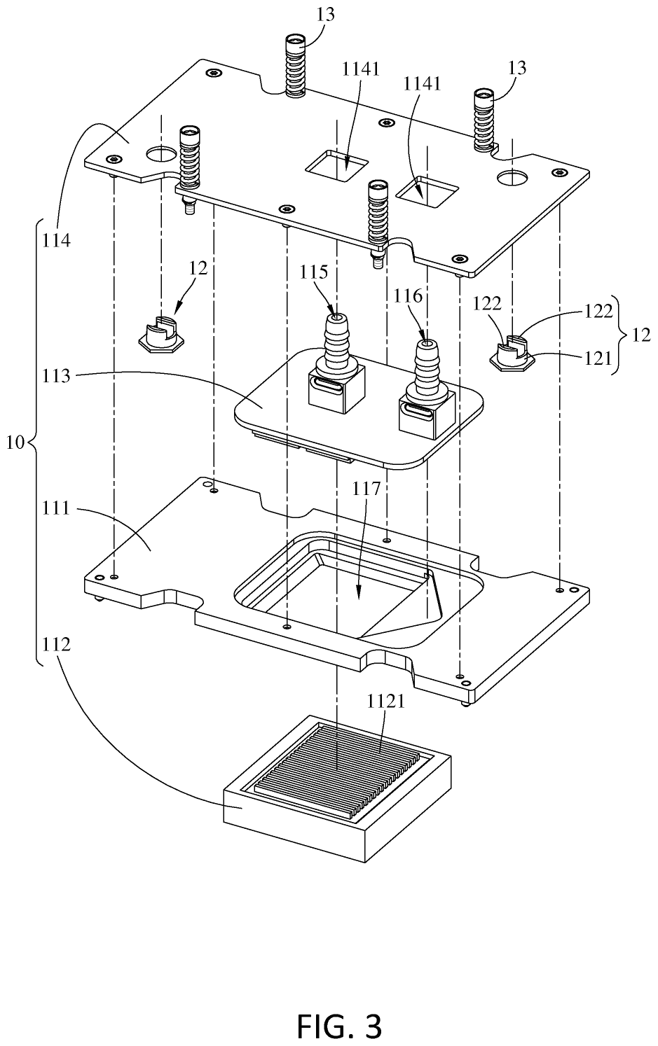

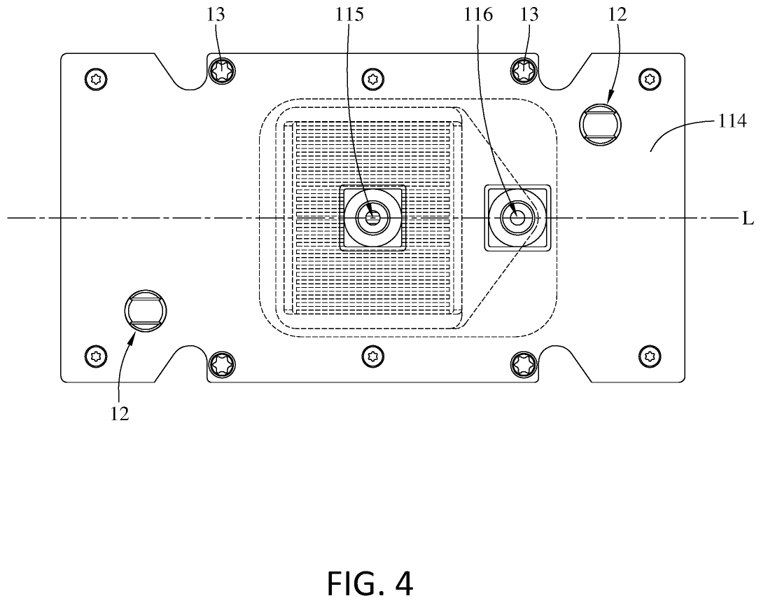

FIG. 3 shows an exploded view of the heat exchanger 10 and the cage 12 of the heat exchanger mounting device system 1000. FIG. 4 shows a top view of the heat exchanger 10 and the cage 12 of the heat exchanger mounting device system 1000. The at least one cage 12 can include a cage body 121 having a cage opening 123 receiving the augmented head 213. The at least one heat exchanger 10 can include an inlet port 115 and an outlet port 116. The inlet port 115 and the outlet port 116 are incorporated on the at least one heat exchanger 10, respectively. The at least one cage 12 can be mounted on the at least one heat exchanger 10. The at least one cage 12 may be mounted on the heat exchanger 10 by way of riveting. The augmented head 213 extends through the cage opening 123 in a first direction and rotates within the at least one cage 12 in a second direction different from the first direction. In the second direction, the at least one securing device 21 is secured to the at least one heat exchanger 10, whereby the weight of the at least one heat exchanger 10 thereby is substantially supported by the at least one securing device 21 by way of the at least one cage 12 and augmented head 213. In at least one embodiment, an angle of rotation of the second direction from the first direction is between 0 degrees to 180 degrees and between 0 degrees to −180 degrees, respectively.

In at least one embodiment, the at least one heat exchanger 10 further includes an assembly plate 114, a water block cover 113, a water block body 111, and a water block base 112. The water block body 111 includes a base cavity opening 117. The water block base 112 includes a plurality of heat transfer surface features 1121 incorporated on the water block base 112. The plurality of heat transfer surface features 1121 correspond to the base cavity opening 117. The water block body 111 is mounted on the water block base 112. The assembly plate 114 includes a pair of port openings 1141 and a pair of cage openings 123. The inlet port 115 and the outlet port 116 are mounted on the water block cover 113, respectively. The inlet port 115 and the outlet port 116 correspond to the pair of port openings 1141, respectively. The inlet port 115 and the outlet port 116 may be incorporated along a central axis L of the heat exchanger 10, respectively. The cage body 121 of each at least one cage 12 correspond to the pair of cage openings 123, respectively. Each at least one cage 12 is mounted to the at least one heat exchanger 10 by way of the pair of cage openings 123, respectively. Each at least one cage 12 is mounted on different sides of the central axis L of the at least one heat exchanger 10, respectively. The assembly plate 114 is mounted on the water block body 111 and the water block cover 113 mounted between the assembly plate 114 and the water block body 111. In at least one embodiment, the at least one heat exchanger 10 further includes a plurality of fasteners 13. The plurality of fasteners 13 may be screws used for assembly of the at least one heat exchanger 10 and/or mounting of the at least one heat exchanger 10 on the circuit board 30.

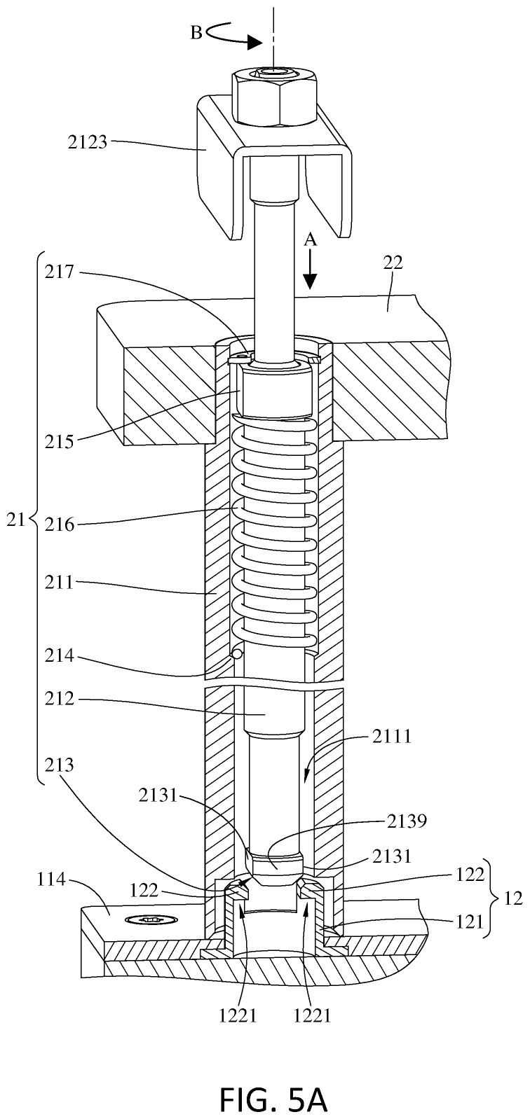

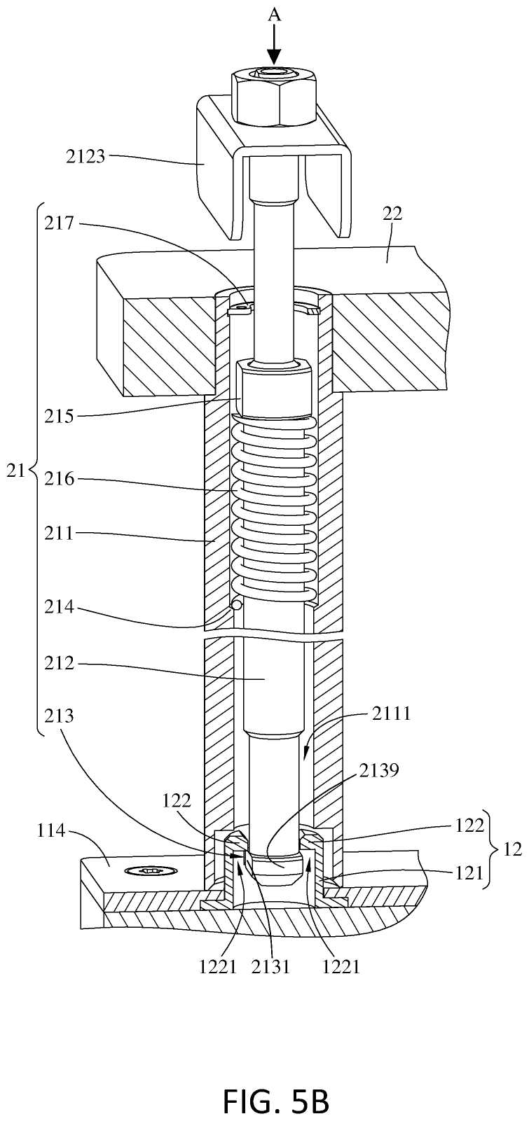

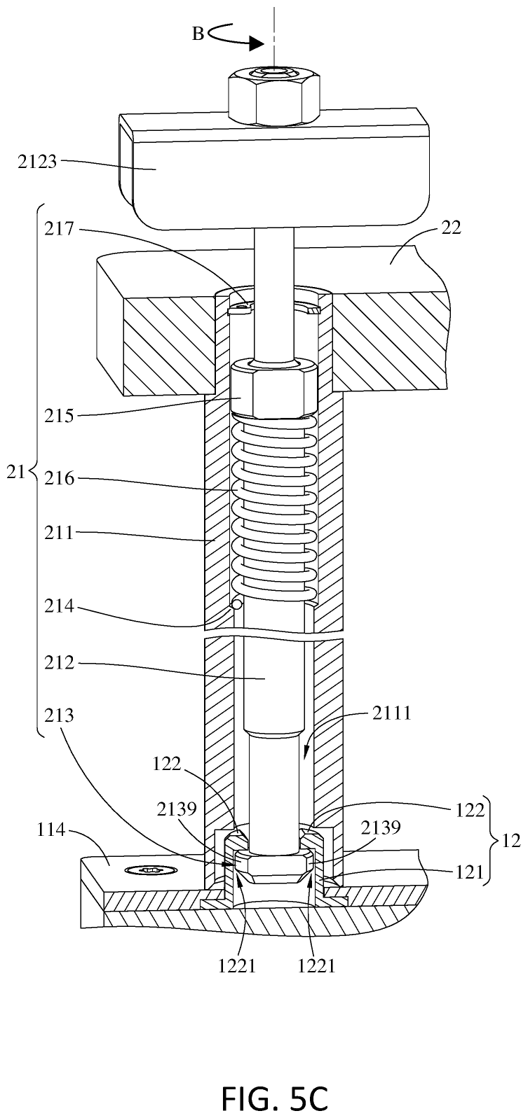

The heat exchanger mounting device 20 of the present disclosure can secure the heat exchanger mounting device 20 to the heat exchanger 10 without screwing. FIGS. 5A to 5C show the process of securing the heat exchanger mounting device 20 to the heat exchanger 10 according to the present disclosure. FIG. 5A shows the original position of the heat exchanger mounting device 20 and the heat exchanger 10. The pin 212 (by way of the knob 2123), is pushed in the downward direction A to extend the augmented head 213 through the cage opening 123 in the first direction as shown in FIG. 5B. The pin 212 is then rotated along the direction B to the second direction as shown in FIG. 5C, which in turn rotates the augmented head 213, to secure the at least one securing device 21 to the heat exchanger 10 to load the heat exchanger 10 mounted to the circuit board 30 in the heat exchanger mounting device system 1000. The knob 2123 visually identifies the first direction being different from the second direction. The weight of the heat exchanger 10 is substantially supported by the at least one securing device 21 by way of the at least one cage 12 and augmented head 213. The pin 212 is then rotated to the first direction, which in turn rotates the augmented head 213, to detach the heat exchanger mounting device 20 from the heat exchanger 10. The pin 212 may also be rotated along the direction B to the second direction, which in turn rotates the augmented head 213, to secure the at least one securing device 21 to the heat exchanger 10 to unload the heat exchanger 10 from the electronic system, for maintenance, repair and/or replacement. No debris causing the electronic components to fail due to multiple torque cycles of fasteners is created. Time needed for loading and unloading of the heat exchanger 10 is decreased. No screwdriver or screwdriver-like fastener tool is needed. The advantages are accentuated when multiple heat exchangers 10 mounted to the circuit board 30 are loaded in the electronics system.

Therefore, embodiments disclosed herein are well adapted to attain the ends and advantages mentioned as well as those that are inherent therein. The particular embodiments disclosed above are illustrative only, as the embodiments disclosed may be modified and practiced in different but equivalent manners apparent to those of ordinary skill in the relevant art having the benefit of the teachings herein. Furthermore, no limitations are intended to the details of construction or design herein shown, other than as described in the claims below. It is therefore evident that the particular illustrative embodiments disclosed above may be altered, combined, or modified and all such variations are considered within the scope and spirit of the present disclosure. The embodiments illustratively disclosed herein suitably may be practiced in the absence of any element that is not specifically disclosed herein and/or any optional element disclosed herein. While compositions and methods are described in terms of “comprising,” “containing,” or “including” various components or steps, the compositions and methods can also “consist essentially of” or “consist of” the various components and steps. All numbers and ranges disclosed above may vary by some number. Whenever a numerical range with a lower limit and an upper limit is disclosed, any number and any included range falling within the range is specifically disclosed. In particular, every range of values (of the form, “from about a to about b,” or, equivalently, “from approximately a to b,” or, equivalently, “from approximately a-b”) disclosed herein is to be understood to set forth every number and range encompassed within the broader range of values. Also, the terms in the claims have their plain, ordinary meaning unless otherwise explicitly and clearly defined by the patentee. Moreover, the indefinite articles “a” or “an,” as used in the claims, are defined herein to mean one or more than one of the element that it introduces.

What is claimed is:

1. A heat exchanger mounting device, comprising:
a device plate having at least one opening;
at least one securing device including a barrel and a pin, the barrel having a first barrel end and a second barrel end opposite the first barrel end, the first barrel end incorporated in the at least one opening, the pin having a first end and a second end opposite the first end, the second end having an augmented head that at least partially extends through the barrel and is rotatable in the barrel; and
at least one cage including a cage body having a cage opening that receives the augmented head,
wherein:
the at least one cage is mounted on a heat exchanger,
the augmented head extends through the cage opening in a first direction, and
the augmented head rotates within the at least one cage in a second direction different from the first direction to secure the at least one securing device to the heat exchanger, whereby a weight of the heat exchanger thereby is substantially supported by the at least one securing device by way of the at least one cage and augmented head.

2. The heat exchanger mounting device of claim 1, wherein an angle of rotation of the second direction from the first direction is between 0 degrees to 180 degrees and between 0 degrees to −180 degrees, respectively.

3. The heat exchanger mounting device of claim 1, wherein the cage body further comprises a pair of inward-facing overhangs, each pair of inward-facing overhangs disposed on opposing sides of the cage opening, each pair of inward-facing overhangs at least partially defines a receiving cavity, whereby the augmented head is rotatable in the receiving cavity.

4. The heat exchanger mounting device of claim 3, wherein the augmented head comprise a pair of side flat cut outs and a pair of ledges, each pair of side flat cut outs disposed on opposing sides of the augmented head, each pair of ledges disposed on opposing sides of the augmented head different from each pair of side flat cut outs, whereby the augmented head extends through the cage opening in the first direction by way of each pair of side flat cut outs corresponding to each pair of inward-facing overhangs, and whereby a weight of the heat exchanger is substantially supported by the at least one securing device by way of the augmented head in the second direction and at least a part of a top surface of each pair of ledges at least partially being flush against at least a part of a bottom surface of each pair of inward-facing overhangs in the receiving cavity, respectively.

5. The heat exchanger mounting device of claim 4, wherein the barrel further comprises a bore and an internal shoulder, the bore disposed through the barrel from the first barrel end to the second barrel end, the internal shoulder disposed in the bore between the first barrel end and the second barrel end, and wherein the at least one securing device further includes an internal retaining ring, a thrust device, and a spring, the internal retaining ring incorporated in the bore at the first barrel end, the thrust device incorporated surrounding the pin and between the internal retaining ring and the internal shoulder, the spring including a spring first end and a spring second end, the spring disposed surrounding the pin and between the thrust device and the internal shoulder, the spring first end disposed flush with a bottom thrust surface of the thrust device by way of an upward force and the spring second end disposed flush with a top shoulder surface of the internal shoulder by way of a downward force, whereby the pin is pushed in a downward direction to extend the augmented head through the cage opening, and whereby the pin is rotated to the second direction to substantially support the weight of the heat exchanger by the at least one securing device.

6. The heat exchanger mounting device of claim 1, wherein the first end comprises a knob, whereby the knob is rotated to the second direction and is visually identifiable in the second direction and the knob is rotated to the first direction and is visually identifiable in the first direction.

7. The heat exchanger mounting device of claim 1, further comprising at least one handle that is incorporated on the device plate.

8. The heat exchanger mounting device of claim 7, wherein the at least one handle comprises two handles.

9. The heat exchanger mounting device of claim 1, wherein the at least one opening comprises two at least one opening, the at least one securing device includes two at least one securing device, and the at least one cage includes two at least one cage, each of the at least one securing device correspond to each of the at least one opening and each of the at least one cage, respectively.

10. The heat exchanger mounting device of claim 1, further comprises a total of eight heat exchangers, a total of sixteen openings, a total of sixteen securing devices, and a total of sixteen cages, each of the securing devices corresponds to one opening and one cage, respectively.

11. The heat exchanger mounting device of claim 1, wherein the heat exchanger is mounted on a circuit board.

12. A heat exchanger mounting device system, comprising:
a device plate having at least one opening;
at least one securing device including a barrel and a pin, the barrel having a first barrel end and a second barrel end opposite the first barrel end, the first barrel end incorporated in the at least one opening, the pin having a first end and a second end opposite the first end, the second end having an augmented head that at least partially extends through the barrel and is rotatable in the barrel;
at least one cage including a cage body, the cage body having a cage opening that receives the augmented head; and at least one heat exchanger including an inlet port and an outlet port, the inlet port and the outlet port incorporated on the at least one heat exchanger, respectively,
wherein:
the at least one cage is mounted on the at least one heat exchanger,
the augmented head extends through the cage opening in a first direction, and
the augmented head rotates within the at least one cage in a second direction different from the first direction to secure the at least one securing device to the at least one heat exchanger, whereby the weight of the at least one heat exchanger thereby is substantially supported by the at least one securing device by way of the at least one cage and augmented head.

13. The heat exchanger mounting device system of claim 12, wherein the at least one heat exchanger further comprise two at least one heat exchanger, and the heat exchanger mounting device system further comprises an inlet manifold, an outlet manifold, an inlet conduit, an outlet conduit, a plurality of heat exchanger inlet conduits, a plurality of heat exchanger outlet conduits, and a circuit board, whereby an inlet manifold end of the inlet conduit is mounted to a manifold inlet of the inlet manifold, an outlet manifold end of the outlet conduit is mounted to a manifold outlet of the outlet manifold, a heat exchanger inlet conduit end of each plurality of heat exchanger inlet conduits is mounted to each of a plurality of heat exchanger outlets of the inlet manifold, a heat exchanger outlet conduit end of each plurality of heat exchanger outlet conduits is mounted to each of a plurality of heat exchanger inlets of the outlet manifold, a heat exchanger outlet conduit end of each plurality of heat exchanger inlet conduits is mounted to the inlet port, a heat exchanger inlet conduit end of each plurality of heat exchanger outlet conduits is mounted to the outlet port, and each of the at least one heat exchangers is mounted on the circuit board.

14. The heat exchanger mounting device system of claim 13, further comprises a total of eight heat exchangers, a total of sixteen openings, a total of sixteen securing devices, and a total of sixteen cages, wherein each of the securing devices corresponds to one opening and one cage, respectively.

15. The heat exchanger mounting device system of claim 14, wherein the at least one heat exchanger further comprises an assembly plate, a water block cover, a water block body, and a water block base, the water block body comprising a base cavity opening, the water block base including a plurality of heat transfer surface features, the plurality of heat transfer surface features incorporated on the water block base and correspond to the base cavity opening, the water block body mounted on the water block base, the assembly plate including a pair of port openings and a pair of cage openings, the inlet port and the outlet port mounted on the water block cover, respectively, the inlet port and the outlet port corresponding to the pair of port openings, respectively, the cage body of each at least one cage correspond to the pair of cage openings, respectively, whereby each at least one cage is mounted to the at least one heat exchanger by way of the pair of cage openings, respectively, the assembly plate mounted on the water block body, the water block cover mounted between the assembly plate and the water block body.

16. The heat exchanger mounting device system of claim 12, wherein an angle of rotation of the second direction from the first direction is between 0 degrees to 180 degrees and between 0 degrees to −180 degrees, respectively.

17. The heat exchanger mounting device system of claim 12, wherein the cage body further comprises a pair of inward-facing overhangs, each pair of inward-facing overhangs disposed on opposing sides of the cage opening, each pair of inward-facing overhangs at least partially defines a receiving cavity, whereby the augmented head is rotatable in the receiving cavity.

18. The heat exchanger mounting device system of claim 17, wherein the augmented head comprise a pair of side flat cut outs and a pair of ledges, each pair of side flat cut outs disposed on opposing sides of the augmented head, each pair of ledges disposed on opposing sides of the augmented head different from each pair of side flat cut outs, whereby the augmented head extends through the cage opening in the first direction by way of each pair of side flat cut outs corresponding to each pair of inward-facing overhangs, and whereby the weight of the at least one heat exchanger is substantially supported by the at least one securing device by way of the augmented head in the second direction and at least a part of a top surface of each pair of ledges at least partially being flush against at least a part of a bottom surface of each pair of inward-facing overhangs in the receiving cavity, respectively.

19. The heat exchanger mounting device system of claim 18, wherein the barrel further comprises a bore and an internal shoulder, the bore disposed through the barrel from the first barrel end to the second barrel end, the internal shoulder disposed in the bore between the first barrel end and the second barrel end, and wherein the at least one securing device further includes an internal retaining ring, a thrust device, and a spring, the internal retaining ring incorporated in the bore at the first barrel end, the thrust device incorporated surrounding the pin and between the internal retaining ring and the internal shoulder, the spring including a spring first end and a spring second end, the spring disposed surrounding the pin and between the thrust device and the internal shoulder, the spring first end disposed flush with a bottom thrust surface of the thrust device by way of an upward force and the spring second end disposed flush with a top shoulder surface of the internal shoulder by way of a downward force, whereby the pin is pushed in a downward direction to extend the augmented head through the cage opening, and whereby the pin is rotated to the second direction to substantially support the weight of the at least one heat exchanger by the at least one securing device.

20. The heat exchanger mounting device system of claim 12, further comprising at least one handle that is incorporated on the device plate, and wherein the first end comprises a knob, whereby the knob is rotated to the second direction and is visually identifiable in the second direction and the knob is rotated to the first direction and is visually identifiable in the first direction.
